(19) United States
(12) Patent Application Publication
(10) Pub. No.: US 2025/0255118 A1
(43) Pub. Date: Aug. 7, 2025

(54) LIGHT EMITTING APPARATUS, DISPLAY APPARATUS AND ELECTRONIC DEVICE INCLUDING LIGHT EMITTING APPARATUS, AND PHOTOELECTRIC CONVERSION APPARATUS

(71) Applicant: CANON KABUSHIKI KAISHA, Tokyo (JP)

(72) Inventors: HIROMASA TSUBOI, Tokyo (JP); MASATO YAJIMA, Tokyo (JP)

(21) Appl. No.: 19/041,086

(22) Filed: Jan. 30, 2025

(30) Foreign Application Priority Data
Feb. 2, 2024 (JP) 2024-014806

(51) Int. Cl. H10K 59/123; G09G 3/20; H04N 23/63; H10K 50/12; H10K 59/127; H10K 59/131

(52) U.S. Cl. CPC H10K 59/123; H10K 50/12; H10K 59/1275; H10K 59/131; G09G 3/2096; G09G 2370/16; H04N 23/63

(57) ABSTRACT

A light emitting apparatus including a light emitting element, a first transistor and a second transistor arranged on a first face of a silicon substrate, and a third transistor arranged on a peripheral circuit for supplying an image signal to the first transistor. Any one of a source and a drain of the first transistor is connected to a gate electrode of the second transistor. Any one of a source and a drain of the second transistor is connected to the light emitting element. A peak concentration of an impurity concentration in a diffusion region of the second transistor is smaller than a peak concentration of an impurity concentration in a diffusion region of a source or a drain of the third transistor.

### BACKGROUND OF THE INVENTION

### Technical Field

The present invention relates to a light emitting apparatus. For example, the present invention relates to a light emitting apparatus having a light emitting element, a display apparatus and an electronic device including the light emitting apparatus, and a photoelectric conversion apparatus.

### Description of the Related Art

In recent years, display apparatuses including arrays of light emitting elements for emitting light with luminance depending on electric currents flowing in the light emitting elements have been known, and an organic electroluminescence (EL) element has been used as the light emitting element. These display apparatuses are used for various purposes, and there is a demand for highly-functional high-definition display apparatuses depending on the purposes.

Japanese Patent Application Laid-Open No. 2020-71323 (hereinafter, called “PTL 1”) discusses a display apparatus which includes silicide layers in a source and a drain of a drive transistor in a drive circuit of an organic light emitting element in order to reduce the electric resistance.

The silicide layers are arranged in the source and the drain of the transistor described in the PTL 1. The resistance of the transistor can be reduced by arranging the silicide layers. However, there is a possibility that property of a light emitting element is degraded by arranging the silicide layers.

### SUMMARY OF THE INVENTION

The present disclosure is directed to a light emitting apparatus whose leak currents are reduced.

According to an aspect of the present disclosure, a light emitting apparatus includes a light emitting element, a silicon substrate, a first transistor and a second transistor arranged on a first face of the silicon substrate, a peripheral circuit for supplying an image signal to the first transistor, and a third transistor arranged on the peripheral circuit, wherein each of the first transistor, the second transistor, and third transition includes a source and a drain, wherein the second transistor includes a gate electrode, wherein any one of the source and the drain of the first transistor is connected to the gate electrode of the second transistor, wherein any one of the source and the drain of the second transistor is connected to the light emitting element, wherein an impurity concentration in a diffusion region of each of the source and the drain of the second transistor has a concentration distribution having a concentration peak in a first direction heading toward the drain from the source, wherein an impurity concentration in a diffusion region of each of the source and the drain of the third transistor has a concentration distribution having a concentration peak in a second direction heading toward the drain from the source, and wherein a peak concentration of impurities in the diffusion region of the source or the drain of the second transistor is smaller than a peak concentration of impurities in the diffusion region of the source or the drain of the third transistor.

Further features of the present disclosure will become apparent from the following description of exemplary embodiments with reference to the attached drawings.

### BRIEF DESCRIPTION OF THE DRAWINGS

FIG. 1 is a schematic diagram illustrating an example of a light emitting apparatus according to a present exemplary embodiment.

FIG. 2 is a circuit diagram illustrating an example of a pixel circuit of the light emitting apparatus according to a first exemplary embodiment.

FIG. 3A is a plan view illustrating an example of a circuit of the light emitting apparatus according to the first exemplary embodiment.

FIG. 3B is a plan view illustrating an example of a peripheral circuit transistor of the light emitting apparatus according to the first exemplary embodiment.

FIG. 4A is a cross-sectional diagram illustrating an example of the light emitting apparatus according to the first exemplary embodiment. FIG. 4B is a cross-sectional diagram illustrating an example of the peripheral circuit transistor of the light emitting apparatus according to the first exemplary embodiment.

FIG. 5 is a cross-sectional diagram illustrating an example of a light emitting apparatus according to a second exemplary embodiment.

FIG. 6A is a cross-sectional diagram illustrating an example of a light emitting apparatus according to a third exemplary embodiment. FIG. 6B is a cross-sectional diagram illustrating an example of a peripheral circuit transistor of the light emitting apparatus according to the third exemplary embodiment.

FIG. 7 is a schematic diagram illustrating an example of a light emitting apparatus according to a fourth exemplary embodiment.

FIG. 8 is a circuit diagram illustrating an example of a pixel circuit of the light emitting apparatus according to the fourth exemplary embodiment.

FIG. 9 is a plan view illustrating an example of a circuit of the light emitting apparatus according to the fourth exemplary embodiment.

FIG. 10 is a cross-sectional diagram illustrating an example of the light emitting apparatus according to the fourth exemplary embodiment.

FIG. 11 is a schematic diagram illustrating an example of a light emitting apparatus according to a fifth exemplary embodiment.

FIG. 12 is a circuit diagram illustrating an example of a pixel circuit of the light emitting apparatus according to the fifth exemplary embodiment.

FIG. 13 is a plan view illustrating an example of a circuit of the light emitting apparatus according to the fifth exemplary embodiment.

FIG. 14 is a cross-sectional diagram illustrating an example of the light emitting apparatus according to the fifth exemplary embodiment.

FIG. 15 is a circuit diagram illustrating an example of an inverter circuit of a light emitting apparatus according to a sixth exemplary embodiment.

FIG. 16 is a plan view illustrating an example of the inverter circuit of the light emitting apparatus according to the sixth exemplary embodiment.

FIG. 17 is a cross-sectional diagram illustrating an example of the inverter circuit of the light emitting apparatus according to the sixth exemplary embodiment.

FIG. 18 is a schematic diagram illustrating an example of a display apparatus according to an exemplary embodiment of the present disclosure.

FIG. 19A is a schematic diagram illustrating an example of an image capturing apparatus according to an exemplary embodiment of the present disclosure. FIG. 19B is a schematic diagram illustrating an example of an electronic device according to an exemplary embodiment of the present disclosure.

FIGS. 20A and 20B are schematic diagrams illustrating examples of a display apparatus according to an exemplary embodiment of the present disclosure.

FIGS. 21A and 21B are schematic diagrams illustrating examples of a wearable device according to an exemplary embodiment of the present disclosure.

### DESCRIPTION OF THE EMBODIMENTS

A light emitting apparatus according to an exemplary embodiment of the present disclosure includes a light emitting element, a first transistor and a second transistor arranged on a first face of a silicon substrate, and a third transistor arranged on a peripheral circuit for supplying an image signal to the first transistor, wherein any one of a source and a drain of the first transistor is connected to a gate electrode of the second transistor, wherein any one of a source and a drain of the second transistor is connected to the light emitting element, wherein an impurity concentration in a diffusion region of each of the source and the drain of the second transistor has a concentration distribution having a concentration peak in a first direction heading toward the drain from the source, wherein an impurity concentration in a diffusion region of each of a source and a drain of the third transistor has a concentration distribution having a concentration peak in a second direction heading toward the drain from the source, and wherein a peak concentration of impurities in the diffusion region of the source or the drain of the second transistor is smaller than a peak concentration of impurities in the diffusion region of the source or the drain of the third transistor.

Hereinafter, exemplary embodiments are described in detail with reference to the appended drawings. The below-described exemplary embodiments are not intended to limit the invention according to the scope of the appended claims. Although a plurality of features is described in the exemplary embodiments, not all of the features are essentially required, and the plurality of features may be optionally combined. Further, in the appended drawings, same reference numerals are applied to constituent elements identical or similar to each other, and duplicative descriptions will be omitted.

Further, in the below-described exemplary embodiments, a drive transistor is connected to an anode of an organic light emitting element, and all of transistors are P-type transistors. However, the light emitting apparatus according to the present disclosure is not limited to the above. A polarity and a conductivity type can be opposite to the above-described polarity and conductivity type. Further, the transistor can be any of a P-type transistor or an N-type transistor, and a supplied potential and a connection may be changed as appropriate according to the conductivity type and the polarity when any changes are to be made.

In the below-described exemplary embodiments, a peripheral circuit may be arranged on a silicon substrate the same as the silicon substrate the transistor such as the drive transistor is arranged, or may be arranged on a second silicon substrate different from the above-described silicon substrate.

A light emitting element described in this specification documents can be an organic light emitting element having a light emitting portion consisting of a light emitting layer containing organic compounds or an inorganic light emitting element having a light emitting portion containing inorganic compounds.

The organic light emitting element has an organic layer including a light emitting layer between an anode electrode and a cathode electrode. The organic layer may include any one or more than one of a hole injection layer, a hole transport layer, an electron injection layer, and an electron transport layer, in addition to the light emitting layer. A display apparatus including the organic light emitting element is one example of the light emitting apparatus, and is also called an organic light emitting apparatus. In the following exemplary embodiments, examples of the light emitting apparatus using the organic light emitting element are described.

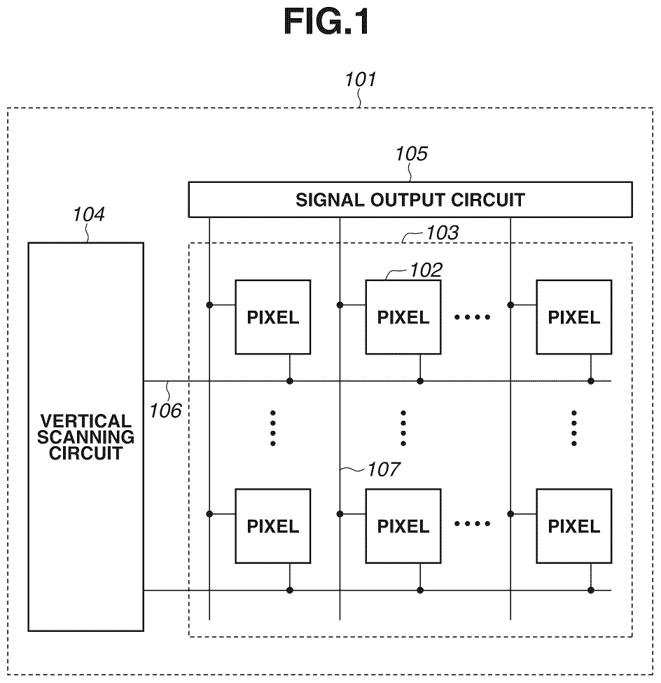

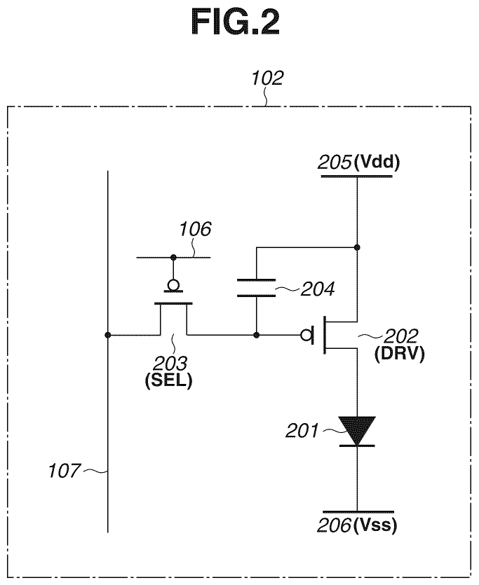

FIG. 1 is a schematic diagram illustrating an example of a light emitting apparatus 101 according to a first exemplary embodiment. A light emitting apparatus 101 includes a pixel array portion 103 and a peripheral circuit portion arranged in the peripheries of the pixel array portion 103. The pixel array portion 103 includes a plurality of pixels 102 arranged in a two-dimensional matrix state, and each of the pixels 102 includes an organic light emitting element 201 (illustrated in FIG. 2).

The light emitting apparatus 101 includes a peripheral circuit portion for driving the pixels 102. For example, the peripheral circuit portion includes a vertical scanning circuit 104 and a signal output circuit 105. A first scanning line 106 is arranged for each row of pixels 102 in the pixel array portion 103 along the row direction. Further, a signal line 107 is arranged for each column of pixels 102 along the column direction.

The first scanning line 106 is connected to each output terminal of a corresponding row arranged on the vertical scanning circuit 104. Further, the signal line 107 is connected to each output terminal of a corresponding column, arranged on the signal output circuit 105. The vertical scanning circuit 104 supplies a write control signal for controlling a timing at which the video signal is written into each of the pixels 102 in the pixel array portion 103 to the first scanning line 106. The signal output circuit 105 outputs a luminance signal having a voltage depending on luminance information.

FIG. 2 is a circuit diagram illustrating an example of a pixel circuit included in the light emitting apparatus 101 in FIG. 1. The pixel 102 includes a light emitting element 201, a drive transistor (DRV) 202, a write transistor (SEL) 203, and a first capacitance element 204. One of a source and a drain of the drive transistor 202 is connected to a first electrode of the light emitting element 201, and another one of the source and the drain of the drive transistor 202 is connected to a first power source terminal 205 (hereinafter, also called “Vdd 205”). A second electrode of the light emitting element 201 is connected to a second power source terminal 206 (hereinafter, also called “Vss 206”).

One of a source and a drain of the write transistor 203 is connected to a gate electrode of the drive transistor 202, and another one of the source and the drain of the write transistor 203 is connected to the signal line 107. A gate electrode of the write transistor 203 is connected to the first scanning line 106.

The first capacitance element 204 is connected to a gate of the drive transistor 202 and any one of the source and the drain (in FIG. 2, the source) of the drive transistor 202, and retains a luminance signal in the pixel 102. The first capacitance element 204 can be any one of a parasitic capacitance, a metal oxide semiconductor (MOS) gate-channel capacitance, a capacitance having a metal-insulator-metal (MIM) structure, and a capacitance having a metal-oxide-metal (MOM) structure.

In the present exemplary embodiment, the drain of the drive transistor 202 is connected to the anode of the light emitting element 201, and the source of the drive transistor 202 is connected to the first power source terminal (Vdd) 205.

The first capacitance element 204 is connected to the gate electrode of the drive transistor 202 and the source of the drive transistor 202, and retains a luminance signal in the pixel 102. The first capacitance element 204 according to the present exemplary embodiment has a MIM structure.

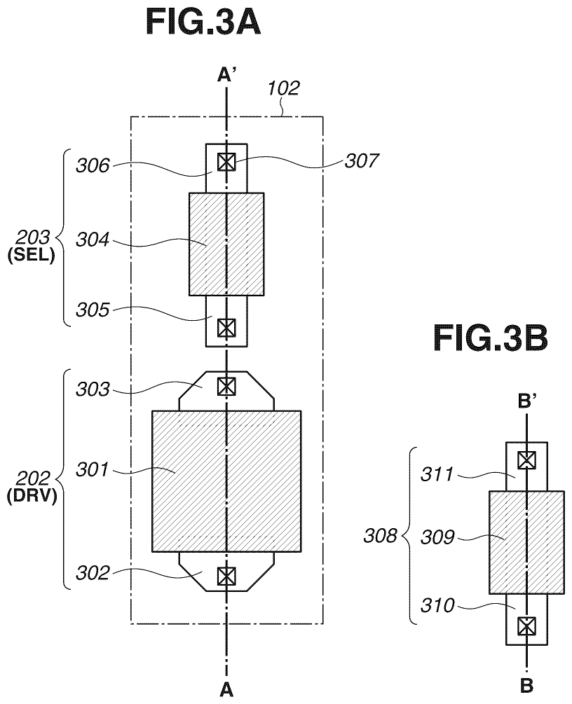

FIG. 3A is a plan view illustrating an example of the circuit illustrated in FIG. 2. The drive transistor 202 includes a gate electrode 301, a source 302, and a drain 303.

The write transistor 203 includes a gate electrode 304, a source 305, and a drain 306. Contact wiring 307 is connected to wiring in another layer.

FIG. 3B is a plan view illustrating an example of a transistor in the peripheral circuit. A peripheral circuit transistor 308 includes a gate electrode 309, a source 310, and a drain 311. The peripheral circuit supplies an image signal to the write transistor 203. Herein, the image signal is a signal for controlling a timing the write transistor 203 is turned on, or a luminance signal.

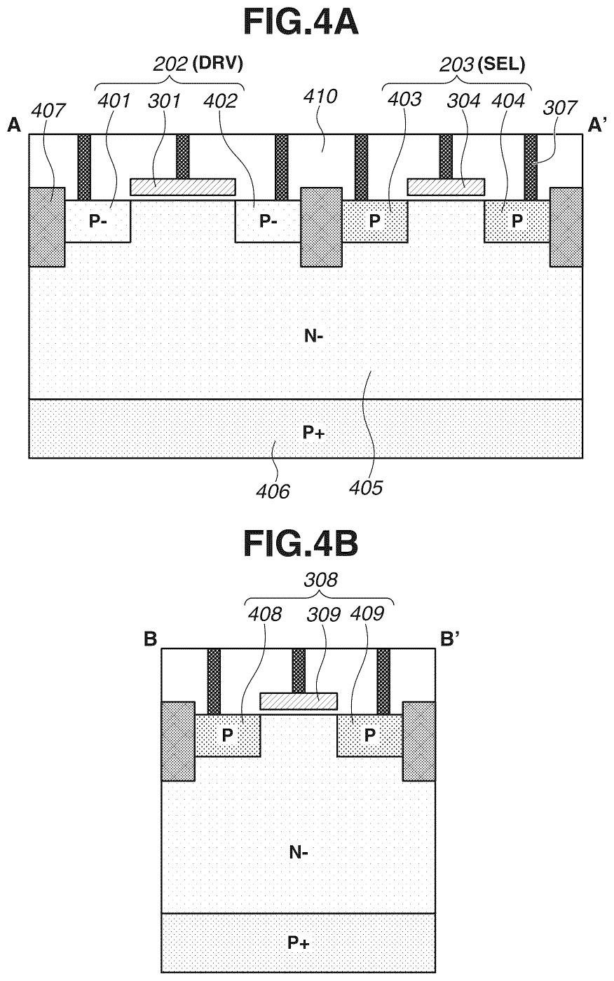

FIG. 4A is a cross-sectional diagram taken along a line A-A′ in the plan view in FIG. 3A. The transistors 202, 203, and 308 according to the present exemplary embodiment are arranged on the upper side of an N-type well layer 405 arranged on a first face of a P-type silicon substrate 406. Specifically, the drive transistor 202 and the write transistor 203 are arranged on the upper side of the N-type well layer 405, and each of the transistors 202 and 203 is isolated by an insulator isolation portion 407. Any of isolation methods, a shallow trench isolation (STI) method, a local oxidation of silicon (LOCOS) isolation method, and an N-type diffusion layer isolation method can be used for the insulator isolation portion 407.

An insulation layer 410 is arranged between the light emitting element 201 and the first face of the silicon substrate. The insulation layer 410 is also called an interlayer insulation layer, and constitutes a wiring layer of the light emitting apparatus 101. The contact wiring 307 passes through an opening formed on the insulation layer 410 and makes contact with the sources, the drains, and the gate electrodes of the drive transistor 202 and the write transistor 203.

FIG. 4B is a cross-sectional diagram taken along a line B-B′ in the plan view in FIG. 3B. As illustrated in FIG. 4B, the source and the drain of the peripheral circuit transistor 308 are respectively formed of P-type diffusion layers 408 and 409.

The source and the drain of the drive transistor 202 of the light emitting apparatus 101 according to the present exemplary embodiment are respectively formed of low-concentration P-type diffusion layers 401 and 402, and the diffusion layers 401 and 402 have concentration distributions having concentration peaks in a direction heading toward the drain from the source. The peak concentration of each of the P-type diffusion layers 401 and 402 is lower than the peak concentration of each of the P-type diffusion layers 408 and 409 of the peripheral circuit transistor 308. Herein, the peak concentration refers to a concentration at a concentration peak.

In other words, an impurity concentration in a diffusion region of each of the source and the drain of the drive transistor 202 has a concentration distribution having a peak concentration in a first direction heading toward the drain from the source, and an impurity concentration in a diffusion region of each of the source and the drain of the peripheral circuit transistor 308 has a concentration distribution having a peak concentration in a second direction heading toward the drain from the source.

A peak concentration of impurities in the diffusion region of the source or the drain of the drive transistor 202 is smaller than a peak concentration of impurities in the diffusion region of the source or the drain of the peripheral circuit transistor 308.

Through the above-described configuration, electric field intensities between the source and the drain of the drive transistor 202 and the N-type well layer 405 can be reduced, so that the leak currents flowing into the source and the drain from the N-type well layer 405 can also be reduced. Therefore, the leak currents flowing into the light emitting element 201 from the drive transistor 202 can also be reduced, so that high-definition black color can be displayed.

According to the present exemplary embodiment, a peak concentration of impurities in the drive transistor 202 is smaller than a peak concentration of impurities in the peripheral circuit transistor 308. However, the invention is not limited to the above, and the peak concentration of impurities in another transistor may be smaller than the peak concentration of impurities in the peripheral circuit transistor 308.

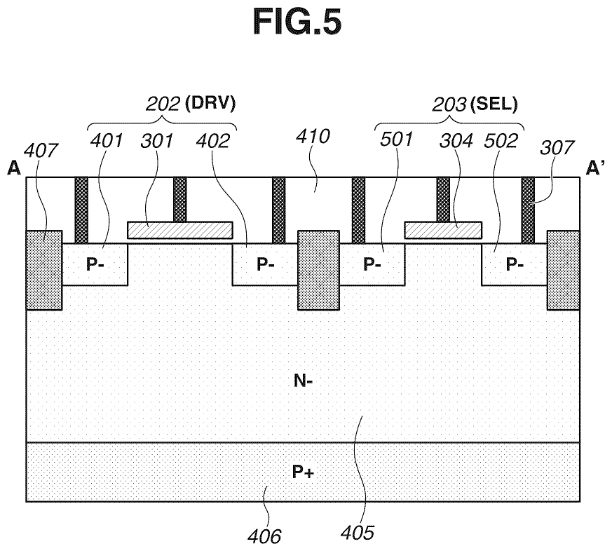

FIG. 5 is a cross-sectional diagram of a light emitting apparatus 101 according to a second exemplary embodiment, taken along a line A-A′ in FIG. 3A. In the present exemplary embodiment, a source and a drain of the write transistor 203 are also formed of low-concentration P-type diffusion layers in addition to the source and the drain of the drive transistor 202. Hereinafter, the present exemplary embodiment is described with respect to the different points from the other exemplary embodiments.

A source and a drain of the write transistor 203 are respectively formed of low-concentration P-type diffusion layers 501 and 502, and each of the diffusion layers 501 and 502 has a concentration distribution having a peak concentration in a direction heading toward the drain from the source. A peak concentration of each of the P-type diffusion layers 501 and 502 is lower than a peak concentration of each of the P-type diffusion layers 408 and 409 of the peripheral circuit transistor 308.

In other words, an impurity concentration in the diffusion region of each of the source and the drain of the write transistor 203 has a concentration distribution having a concentration peak in a third direction heading toward the drain from the source, an impurity concentration in the diffusion region of each of the source and the drain of the peripheral circuit transistor 308 has a concentration distribution having a concentration peak in a second direction heading toward the drain from the source, and a peak concentration of impurities in the diffusion region of the source or the drain of the write transistor 203 is smaller than a peak concentration of impurities in the diffusion region of the source or the drain of the peripheral circuit transistor 308. Herein, the peak concentration refers to a concentration at a concentration peak.

Through the above-described configuration, electric field intensities between the source and the drain of the write transistor 203 and the N-type well layer 405 can be reduced, so that the leak currents flowing into the source and the drain from the N-type well layer 405 can also be reduced. Therefore, the leak currents flowing into the first capacitance element 204 can also be reduced, so that fluctuations of a luminance signal retained by the first capacitance element 204 can be reduced. Accordingly, the organic light emitting element 201 can stably emit light at a predetermined luminance.

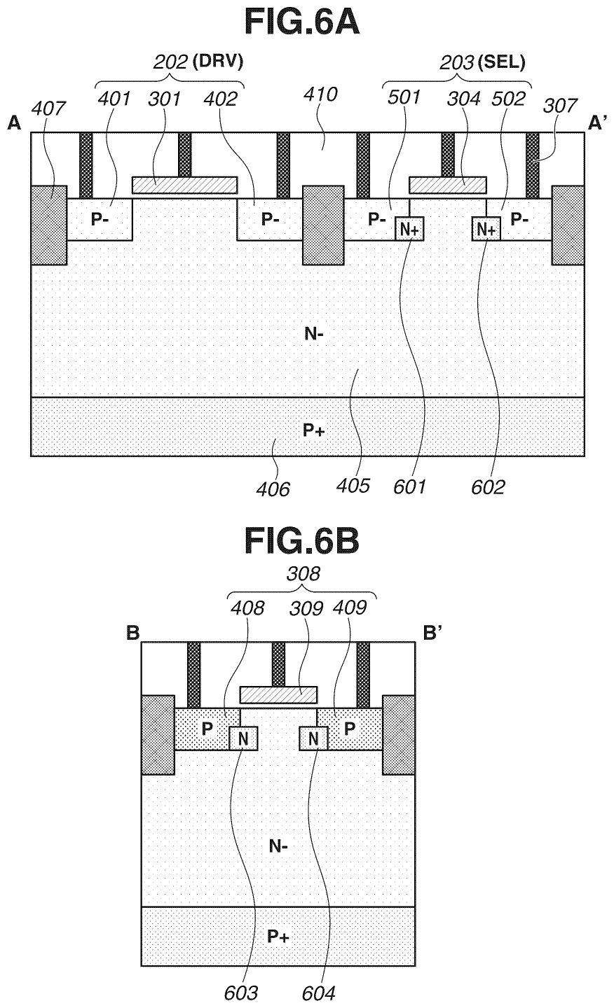

FIG. 6A is a cross-sectional diagram of a light emitting apparatus 101 according to a third exemplary embodiment, taken along a line A-A′ in FIG. 3A. According to the present exemplary embodiment, each of the write transistor 203 and the peripheral circuit transistor 308 has a Halo structure. Hereinafter, the present exemplary embodiment is described with respect to the different points from the other exemplary embodiments.

High-concentration N-type diffusion layers 601 and 602 serving as Halo injection layers are arranged to be adjacent to the low-concentration P-type diffusion layers 501 and 502 in the write transistor 203, and the N-type well layer 405 with a lower concentration is arranged between the high-concentration N-type diffusion layers 601 and 602.

A Halo injection layer is not arranged on the drive transistor 202 according to the present exemplary embodiment. The drive transistor 202 supplies subthreshold currents to the organic light emitting element 201. Therefore, in a case where the Halo injection layer is arranged on the drive transistor 202, the subthreshold currents may considerably vary for each pixels 102 even if the variation of concentration in the Halo injection layer is small. Because the Halo injection layer is not arranged on the drive transistor 202, variation in the amount of electric currents supplied to the organic light emitting element 201 from the drive transistor 202 can be reduced.

FIG. 6B is a cross-sectional diagram of the light emitting apparatus 101 according to the present exemplary embodiment, taken along a line B-B′ in FIG. 3B. N-type diffusion layers 603 and 604 serving as Halo injection layers are arranged to be adjacent to the P-type diffusion layers 408 and 409 in the peripheral circuit transistor 308, and the N-type well layer 405 with a lower concentration is arranged between the N-type diffusion layers 603 and 604. According to the present exemplary embodiment, a peak concentration of each of the high-concentration N-type diffusion layers 601 and 602 constituting the write transistor 203 is higher than a peak concentration of each of the N-type diffusion layers 603 and 604 constituting the peripheral circuit transistor 308. However, the invention is not limited thereto, and the concentration of the Halo injection layer may be adjusted as appropriate depending on the amount of leak currents. Further, the magnitude relationship described above can be reversed.

The light emitting apparatus 101 according to the present exemplary embodiment includes the Halo injection layer in the diffusion region of each of the source and the drain of the write transistor 203, and a polarity of the Halo injection layer is opposite to a polarity of the diffusion region. In other words, each of the Halo injection layers has a polarity the same as a polarity of a channel formed when the transistor is turned on.

Then, the peripheral circuit transistor 308 includes the Halo injection layer in the diffusion region of each of the source and the drain, and a polarity of the Halo injection layer is opposite to a polarity of the diffusion region.

A peak concentration of an impurity concentration in each of the Halo injection layers included in the write transistor 203 is higher than a peak concentration of an impurity concentration in each of the Halo injection layers included in the peripheral circuit transistor 308. In the present exemplary embodiment, a relationship between the peak concentrations has been described as the above. However, the peak concentration of the impurity concentration in each of the Halo injection layers included in the write transistor 203 may simply be different from the peak concentration of the impurity concentration in each of the Halo injection layers included in the peripheral circuit transistor 308. It is possible to adjust the peak concentration of the impurity concentration by controlling and adjusting the leak currents.

Through the above-described configuration, the leak currents flowing into the drain of the write transistor 203 and the first capacitance element 204 from the source of the write transistor 203 can be reduced, and fluctuations in the luminance signal retained by the first capacitance element 204 can be suppressed. Accordingly, the organic light emitting element 201 can stably emit light at a predetermined luminance. Further, the leak currents flowing into the drain from the source of the peripheral circuit transistor 308 can be suppressed, so that consumption of electric currents at the peripheral circuit portion can be reduced.

A light emitting apparatus 101 according to a fourth exemplary embodiment includes a light emission control transistor 801 arranged between the power source for supplying electric currents to the light emitting element 201 and the drive transistor 202. More specifically, the light emitting apparatus 101 includes a light emission control transistor 801 for controlling the electric currents supplied to the drive transistor 202 from the Vdd 205. Hereinafter, the present exemplary embodiment is described with respect to the different points from the other exemplary embodiments. The light emission control transistor 801 is also called a fourth transistor following the drive transistor 202, the write transistor 203, and the peripheral circuit transistor 308.

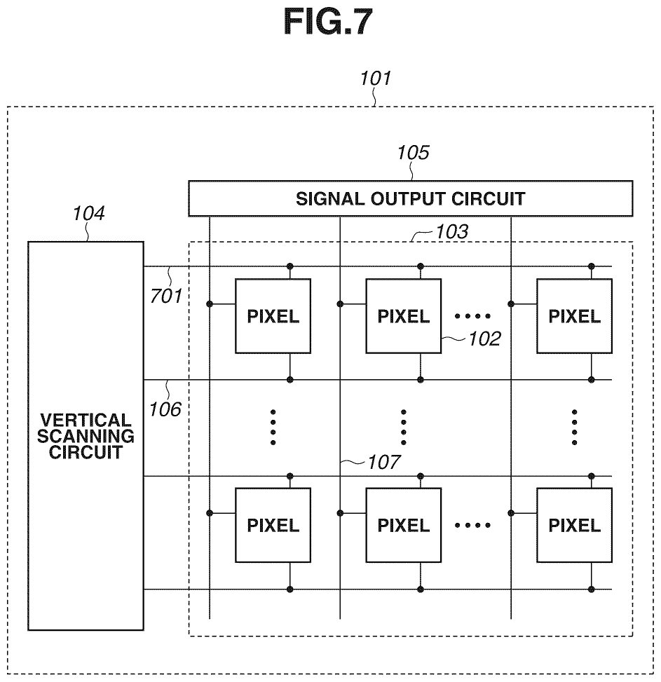

FIG. 7 is a schematic diagram illustrating an example of the light emitting apparatus 101 according to the present exemplary embodiment. A second scanning line 701 is arranged for each row of pixels 102 in the pixel array portion 103 along the row direction. The second scanning line 701 is connected to each output terminal of a corresponding row, arranged on the vertical scanning circuit 104, and supplies a light emission control signal to each of the pixels 102.

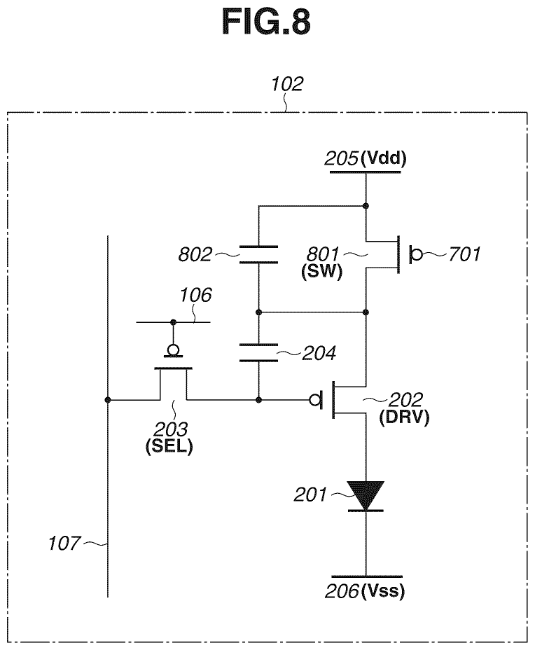

FIG. 8 is a circuit diagram illustrating an example of a pixel circuit included in the light emitting apparatus 101 in FIG. 7. One of a source and a drain (in FIG. 8, the drain) of the light emission control transistor 801 is connected to one of a source and a drain (in FIG. 8, the source) of the drive transistor 202. Another one (in FIG. 8, the source) of the light emission control transistor 801 is connected to the Vdd 205. Further, a gate of the light emission control transistor 801 is connected to the second scanning line 701.

The second capacitance element 802 is connected to the drain of the light emission control transistor 801 and the Vdd 205. The second capacitance element 802 can be any one of a parasitic capacitance, a MOS gate-channel capacitance, a capacitance having a MIM structure, and a capacitance having a MOM structure.

In response to the light emission control signal applied to the gate from the vertical scanning circuit 104 via the second scanning line 701, the light emission control transistor 801 is turned on and allows the electric currents supplied to the drive transistor 202 from the Vdd 205. This enables the drive transistor 202 to make the organic light emitting element 201 emit light. In other words, the light emission control transistor 801 functions as a transistor for controlling emission/non-emission of light from the organic light emitting element 201. As described above, through the switching operation of the light emission control transistor 801, it is possible to execute so-called duty control, i.e., control of a ratio between the periods when the light emitting element 201 emits/does not emit light. By executing the duty control, it is possible to reduce occurrence of an afterimage blur caused by emission of light from the pixel 102 over one frame period, so that image quality can particularly be improved at the time of moving image capturing.

Further, because of manufacturing variations, a threshold of the drive transistor 202 may vary from pixel to pixel. In a case where the same signal voltage is written into a plurality of pixels for emitting light of a same color, the amount of electric currents flowing in the drive transistor 202 varies from pixel to pixel, so that variation arises in the light emission amount. Therefore, before the signal voltage is written, a so-called threshold correction operation for making the drive transistor 202 retain a threshold between the gate and the source is executed. Through the threshold correction operation, variation in the amount of electric currents flowing in the drive transistor 202 in each pixel can be reduced, so that light can be emitted more uniformly.

In the threshold correction operation, after the electric currents are supplied to the organic light emitting element 201 via the light emission control transistor 801 and the drive transistor 202, the light emission control transistor 801 is turned off. With this operation, electric currents flow into the organic light emitting element 201 until the voltage between the gate and the source of the drive transistor 202 becomes stable, and the threshold correction is executed.

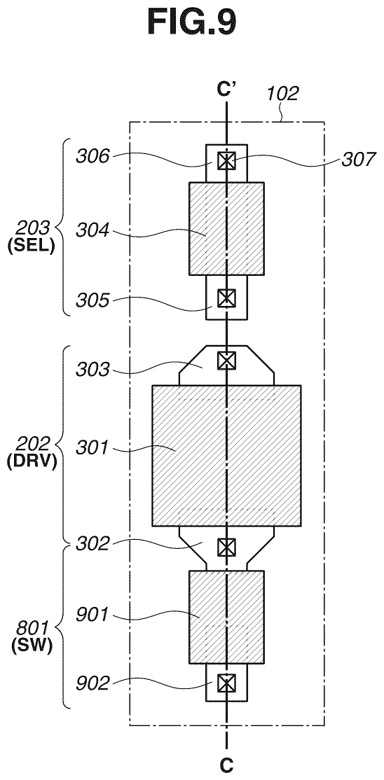

FIG. 9 is a plan view illustrating an example of the circuit in FIG. 8. The light emission control transistor 801 includes a gate electrode 901, a source 902, and a drain 302.

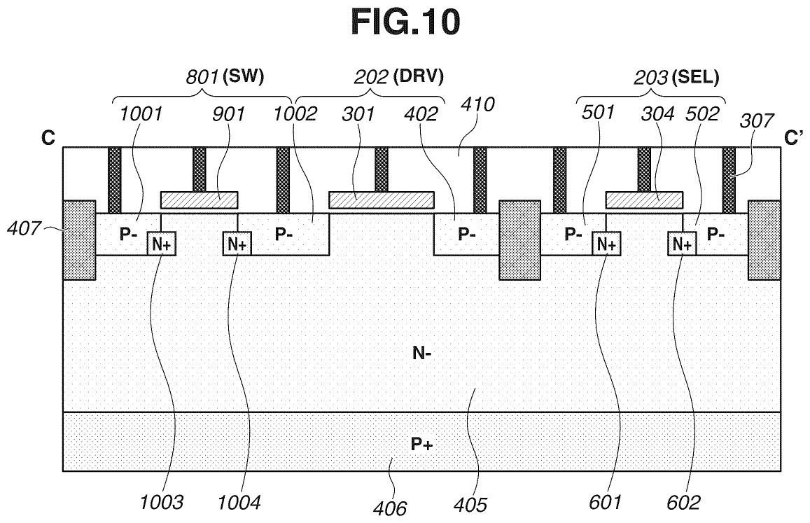

FIG. 10 is a cross-sectional diagram taken along a line C-C′ in the plan view in FIG. 9. A source and a drain of the light emission control transistor 801 are respectively formed of low-concentration P-type diffusion layers 1001 and 1002, and a peak concentration of each of the P-type diffusion layers 1001 and 1002 is lower than a peak concentration of each of the P-type diffusion layers 408 and 409 in the peripheral circuit transistor 308. Further, high-concentration N-type diffusion layers 1003 and 1004 serving as Halo injection layers are arranged to be adjacent to low-concentration P-type diffusion layers 1001 and 1002, and the N-type well layer 405 with a lower concentration is arranged between the high-concentration N-type diffusion layers 1003 and 1004. According to the present exemplary embodiment, a peak concentration of each of the high-concentration N-type diffusion layers 1003 and 1004 constituting the light emission control transistor 801 is higher than a peak concentration of each of the N-type diffusion layers 603 and 604 constituting the peripheral circuit transistor 308. However, the invention is not limited thereto, and the concentration of the Halo injection layer may be adjusted as appropriate depending on the amount of leak currents. Further, the magnitude relationship described above can be reversed. A concentration of each of the Halo injection layers included in the light emission control transistor 801 may be the same as a concentration of each of the Halo injection layers included in the write transistor 203.

In the present exemplary embodiment, the light emission control transistor 801 is arranged between the power source for supplying electric currents to the light emitting element 201 and the drive transistor 202, and the Halo injection layers are arranged on the light emission control transistor 801.

Further, an impurity concentration in the diffusion region of each of the source and the drain of the light emission control transistor 801 has a concentration distribution having a concentration peak in a fourth direction heading toward the drain from the source, an impurity concentration in the diffusion region of each of the source and the drain of the peripheral circuit transistor 308 has a concentration distribution having a concentration peak in a second direction heading toward the drain from the source, and a peak concentration of impurities in the diffusion region of the source or the drain of the light emission control transistor 801 may be smaller than a peak concentration of impurities in the diffusion region of the source or the drain of the peripheral circuit transistor 308.

Through the above-described configuration, at the time of the threshold correction, the leak currents flowing into the drain of the light emission control transistor 801 and the first capacitance element 204 from the source of the light emission control transistor 801 can be reduced, so that fluctuations of threshold voltage retained by the first capacitance element 204 can be reduced.

A light emitting apparatus 101 according to a fifth exemplary embodiment includes a reset transistor 1201 arranged between a terminal of any one of the drain and the source of the drive transistor 202 connected to the light emitting element 201 and a terminal having a potential lower than that of the power source for supplying electric currents to the light emitting element 201. More specifically, the light emitting apparatus 101 includes the reset transistor 1201 for resetting the light emitting element 201 by connecting the anode of the light emitting element 201 to the third power source terminal (hereinafter, “Vres”) 1202. The reset transistor 1201 is also called a fifth transistor following the light emission control transistor 801. The third power source terminal 1202 may be a terminal having a potential lower than that of the power source for supplying electric currents to the light emitting element 201. The third power source terminal 1202 according to the present exemplary embodiment may simply have a potential for making the reset transistor 1201 reset the light emitting element 201, and is not limited to the present exemplary embodiment. Hereinafter, the present exemplary embodiment is described with respect to the different points from the other exemplary embodiments.

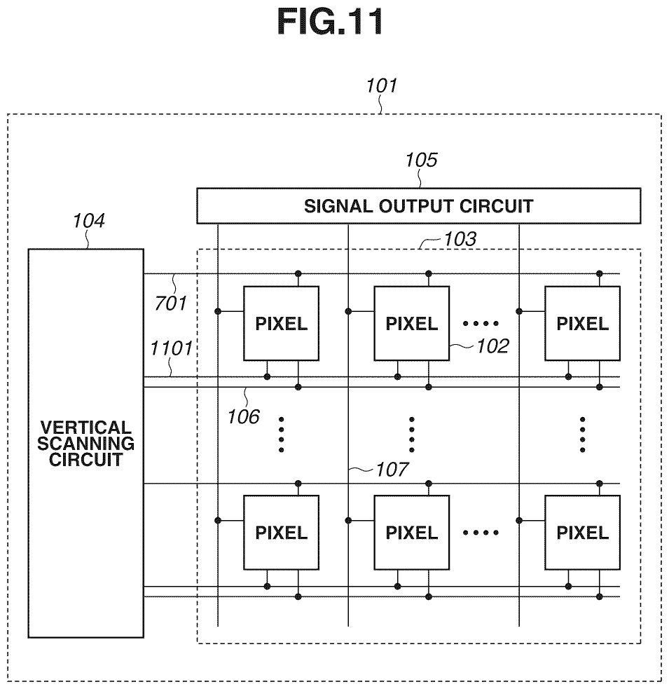

FIG. 11 is a schematic diagram illustrating an example of the light emitting apparatus 101 according to the present exemplary embodiment. A third scanning line 1101 is arranged for each row of pixels 102 in the pixel array portion 103 along the row direction. The third scanning line 1101 is connected to each output terminal of a corresponding row, arranged on the vertical scanning circuit 104, and supplies a reset signal to each of the pixels 102.

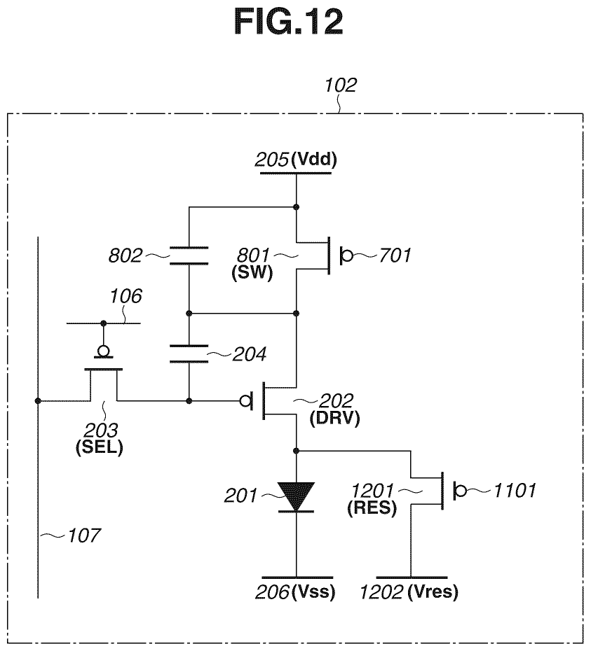

FIG. 12 is a circuit diagram illustrating an example of a pixel circuit included in the light emitting apparatus 101 in FIG. 11. One of a source and a drain (in FIG. 12, the source) of the reset transistor 1201 is connected to one of a source and a drain (in FIG. 12, the drain) of the drive transistor 202. Another one of the source and the drain of the reset transistor 1201 is connected to the Vres 1202. A gate of the reset transistor 1201 is connected to the third scanning line 1101. By turning on the reset transistor 1201, the anode of the organic light emitting element 201 is connected to the Vres 1202, so that a luminance of the organic light emitting element 201 can be brought into a black level. With this configuration, it is possible to realize a high-contrast light emitting apparatus. Further, the reset transistor 1201 is turned off during a light emission period.

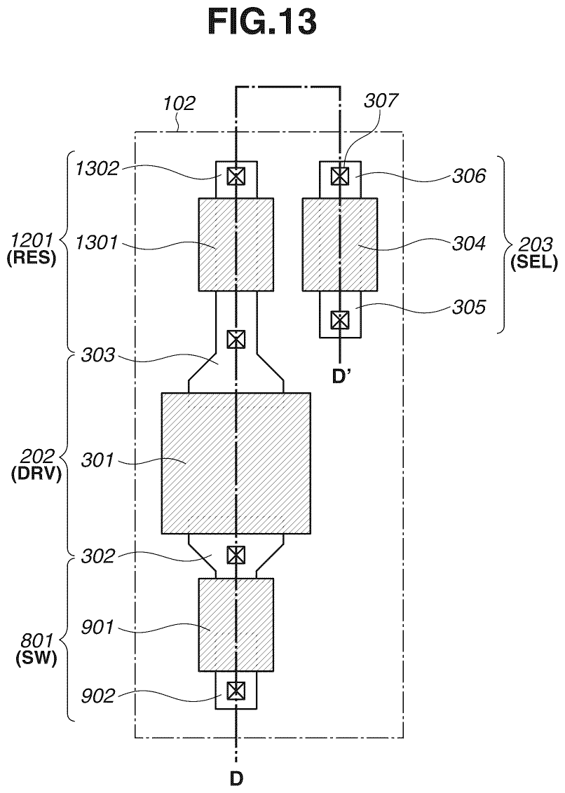

FIG. 13 is a plan view illustrating an example of the circuit in FIG. 12. The reset transistor 1201 includes a gate electrode 1301, a source 303, and a drain 1302. The source node of the reset transistor 1201 is the same as the drain node of the drive transistor 202, and then, the same reference numeral 303 is used.

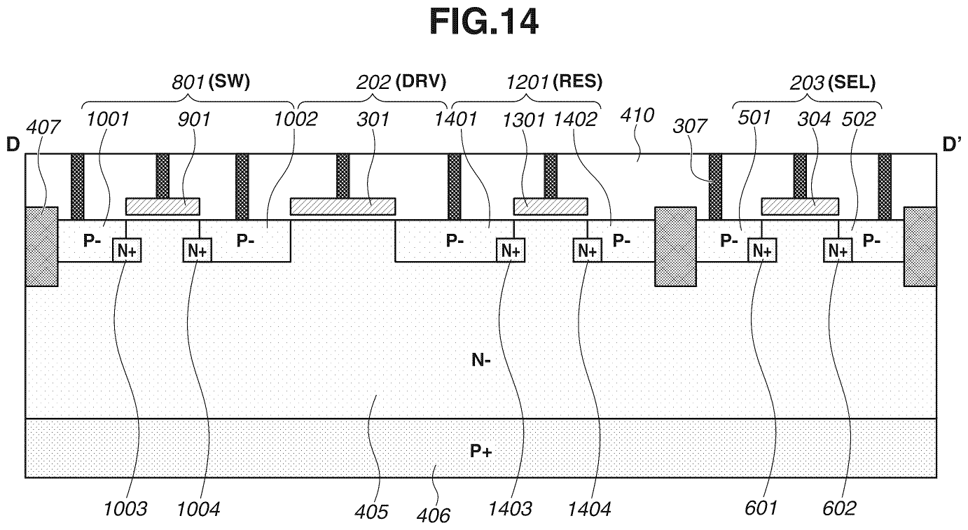

FIG. 14 is a cross-sectional diagram taken along a line D-D′ in the plan view in FIG. 13. A source and a drain of the reset transistor 1201 are respectively formed of low-concentration P-type diffusion layers 1401 and 1402, and a peak concentration of each of the P-type diffusion layers 1401 and 1402 is lower than a peak concentration of each of the P-type diffusion layers 408 and 409 in the peripheral circuit transistor 308. Further, high-concentration N-type diffusion layers 1403 and 1404 serving as Halo injection layers are arranged to be adjacent to low-concentration P-type diffusion layers 1401 and 1402, and the N-type well layer 405 with a lower concentration is arranged between the high-concentration N-type diffusion layers 1403 and 1404. According to the present exemplary embodiment, a peak concentration of each of the high-concentration N-type diffusion layers 1403 and 1404 constituting the reset transistor 1201 is higher than a peak concentration of each of the N-type diffusion layers 603 and 604 constituting the peripheral circuit transistor 308. However, the invention is not limited thereto, and the concentration of the Halo injection layer may be adjusted as appropriate depending on the amount of leak currents. Further, the magnitude relationship described above can be reversed. A concentration of each of the Halo injection layers included in the reset transistor 1201 may be the same as a concentration of each of the Halo injection layers included in the write transistor 203.

The light emitting apparatus 101 according to the present exemplary embodiment includes the reset transistor 1201 arranged between a terminal of the drain or the source of the drive transistor 202 connected to the light emitting element 201 and a terminal having a potential lower than that of the power source for supplying electric currents to the light emitting element 201.

An impurity concentration in the diffusion region of each of the source and the drain of the reset transistor 1201 according to the present exemplary embodiment has a concentration distribution having a concentration peak in a fifth direction heading toward the drain from the source, and an impurity concentration in the diffusion region of each of the source and the drain of the peripheral circuit transistor 308 has a concentration distribution having a concentration peak in a second direction heading toward the drain from the source. A peak concentration of impurities in the diffusion region of the source or the drain of the reset transistor 1201 may be smaller than a peak concentration of impurities in the diffusion region of the source or the drain of the peripheral circuit transistor 308. Herein, the peak concentration refers to a concentration at a concentration peak.

Through the above-described configuration, the leak currents flowing into the drain from the source of the reset transistor 1201 can be reduced. Therefore, during a light emission period, the leak currents flowing into the Vres 1202 from the drive transistor 202 via the reset transistor 1201 can be reduced, so that consumption of electric currents at the pixel 102 can be reduced.

In a light emitting apparatus 101 according to a sixth exemplary embodiment, a transistor for constituting an inverter circuit 1501 within the vertical scanning circuit 104 has a Halo structure. Hereinafter, the present exemplary embodiment is described with respect to the different points from the other exemplary embodiments.

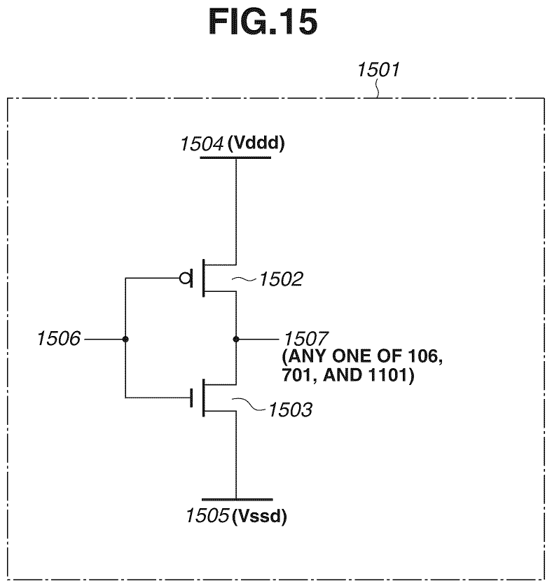

FIG. 15 is a circuit diagram illustrating an example of the inverter circuit 1501 within the vertical scanning circuit 104 included in the light emitting apparatus 101 in FIG. 11. A drain, a source, and a gate of a P-type transistor 1502 are respectively connected to a drain of an N-type transistor 1503, a fourth power source terminal (hereinafter, “Vddd”) 1504, and a gate of the N-type transistor 1503.

A source of the N-type transistor 1503 is connected to a fifth power source terminal (hereinafter, “Vssd”) 1505.

The inverter circuit 1501 includes an input terminal 1506 and an output terminal 1507. The input terminal 1506 is connected to the gate of the P-type transistor 1502 and the gate of the N-type transistor 1503. The output terminal 1507 is connected to the drain of the P-type transistor 1502 and the drain of the N-type transistor 1503, and is further connected to any one of the first scanning line 106, the second scanning line 701, and the third scanning line 1101.

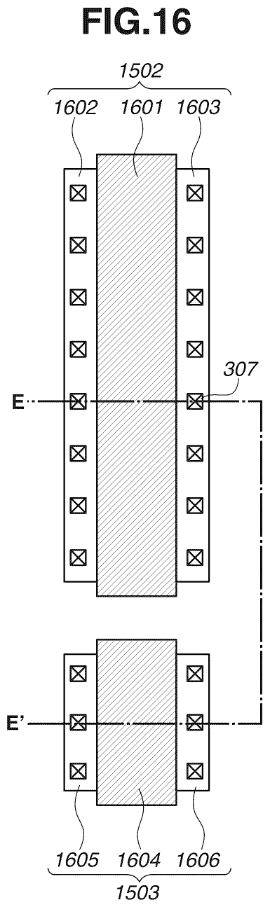

FIG. 16 is a plan view illustrating an example of the circuit in FIG. 15. The P-type transistor 1502 includes a gate electrode 1601, a source 1602, and a drain 1603.

The N-type transistor 1503 includes a gate electrode 1604, a source 1605, and a drain 1606.

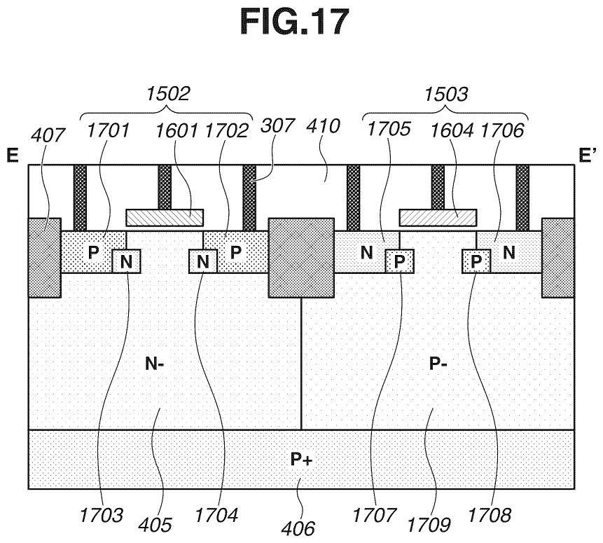

FIG. 17 is a cross-sectional diagram taken along a line E-E′ in the plan view in FIG. 16. The source and the drain of the P-type transistor 1502 are respectively formed of P-type diffusion layers 1701 and 1702. Further, N-type diffusion layers 1703 and 1704 serving as Halo injection layers are arranged to be adjacent to P-type diffusion layers 1701 and 1702, and the N-type well layer 405 with a lower concentration is arranged between the N-type diffusion layers 1703 and 1704.

The source and the drain of the N-type transistor 1503 are respectively formed of N-type diffusion layers 1705 and 1706. Further, P-type diffusion layers 1707 and 1708 serving as Halo injection layers are arranged to be adjacent to the N-type diffusion layers 1705 and 1706, and a P-type well layer 1709 with a lower concentration is arranged between the P-type diffusion layers 1707 and 1708.

Through the above-described configuration, the leak currents flowing into the Vssd 1505 from the Vddd 1504 via the P-type transistor 1502 and the N-type transistor 1503 can be reduced, so that consumption of electric currents at the vertical scanning circuit 104 can be reduced.

### Other Exemplary Embodiments

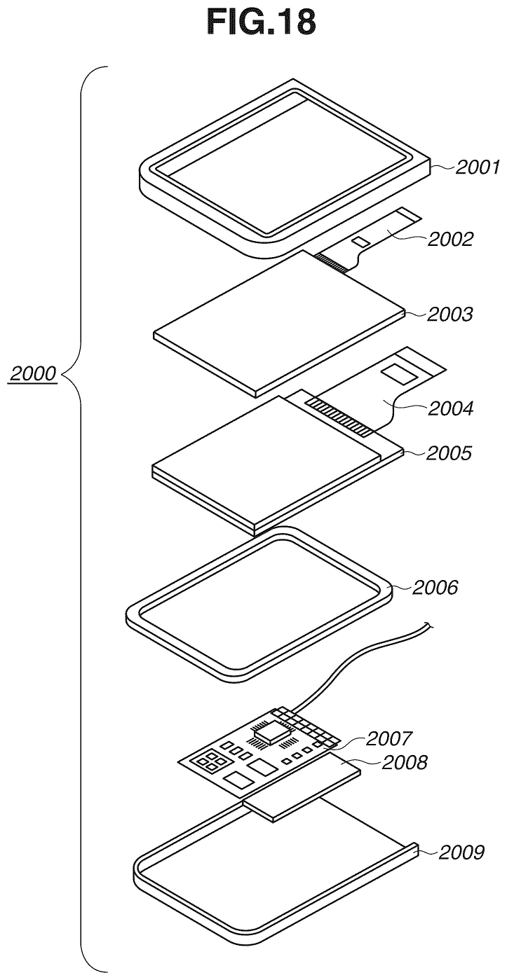

FIG. 18 is a schematic diagram illustrating an example of a display apparatus according to the present exemplary embodiment. A display apparatus 2000 may include a touch panel 2003, a display panel 2005 a frame 2006, a circuit substrate 2007, and a battery 2008 arranged between a top cover 2001 and a bottom cover 2009. Flexible print circuits FPC 2002 and 2004 are connected to the touch panel 2003 and the display panel 2005. A transistor is printed on the circuit substrate 2007. The battery 2008 does not have to be arranged on the display apparatus 2000 if the display apparatus 2000 is not a mobile device, or the battery 2008 may be arranged at another position if the display apparatus 2000 is a mobile device.

The display apparatus according to the present exemplary embodiment may include color filters of red, green, and blue. The color filters of respective colors of red, green and blue may be arranged in a delta array.

The display apparatus according to the present exemplary embodiment may be used for a display unit of a mobile terminal. In this case, the display apparatus may have both of a display function and an operation function. A mobile phone such as a smartphone, a tablet terminal, and a head-mounted display can be given as examples of the mobile terminal.

The display apparatus according to the present exemplary embodiment may be used for a display unit of an image capturing apparatus which includes an optical unit having a plurality of lenses and an image sensor for receiving light passing through the optical unit. The image capturing apparatus may have a display unit for displaying information acquired by the image sensor. Further, the display unit may be a display unit exposed to the outside of the image capturing apparatus or may be a display unit arranged inside a finder. The image capturing apparatus may be a digital camera or a digital video camera.

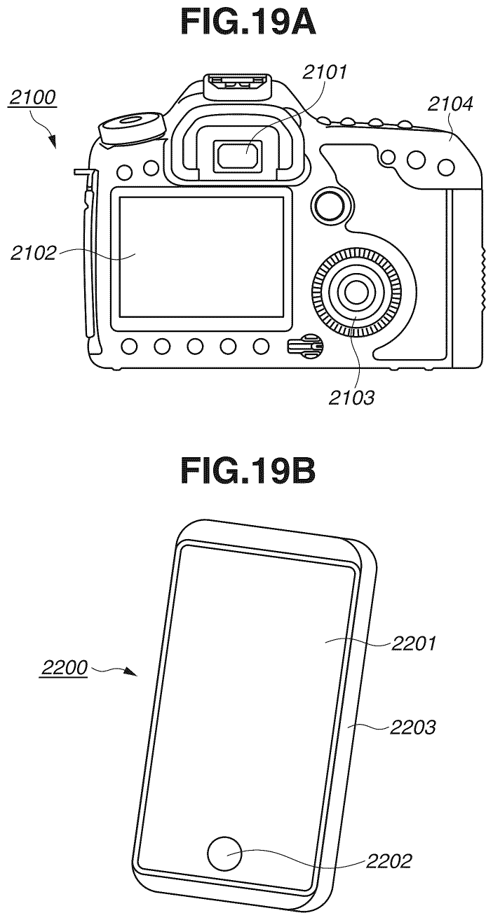

FIG. 19A is a schematic diagram illustrating an example of the image capturing apparatus according to the present exemplary embodiment. An image capturing apparatus 2100 may have a viewfinder 2101, a back-face display 2102, an operation unit 2103, and a housing 2104. The viewfinder 2101 may include the display apparatus according to the present exemplary embodiment. In this case, the display apparatus may display environmental information and image capturing instructions in addition to an image to be captured. Information about intensities and direction of outside light, information about moving speed of an object, and information about a possibility that an object is covered by a shielding object may be displayed as the environmental information.

Because a timing suitable for capturing images lasts for only a moment, it is better to display the above-described information as soon as possible. Accordingly, it is preferable that the display apparatus using an organic light emitting element, described in the present disclosure, be used. This is because the organic light emitting element can quickly return a response. The display apparatus using an organic light emitting element can be used more suitably than the above-described apparatuses and liquid crystal display apparatuses which require display speed.

The image capturing apparatus 2100 includes an optical unit (not illustrated). The optical unit includes a plurality of lenses, and forms an image on an image sensor housed within the housing 2104. The plurality of lenses can adjust a focus by adjusting the relative lens positions. This operation can also be executed automatically. The image capturing apparatus 2100 can also be called a photoelectric conversion apparatus. Instead of sequentially capturing images, the photoelectric conversion apparatus can execute image capturing methods such as a method for detecting a difference from a previous image and a method for cutting out an image from images constantly being recorded.

FIG. 19B is a schematic diagram illustrating an example of an electric device according to the present exemplary embodiment. An electronic device 2200 includes a display unit 2201, an operation unit 2202, and a housing 2203. The housing 2203 may house a circuit, a print substrate on which the circuit is arranged, a battery, and a communication unit. The operation unit 2202 may be a button or a touch panel-type reaction unit. The operation unit 2202 may be a biometric recognition unit which recognizes a fingerprint to release a lock. The communication unit can be a wired or a wireless communication unit which communicates with a remote external apparatus. The electronic device 2200 including the communication unit can also be called a communication device. A lens and an image sensor may be arranged on the electronic device 2200, so that a camera function is also provided to the electronic device 2200. An image captured through the camera function is displayed on the display unit.

A smartphone and a notebook-size personal computer (PC) can be given as examples of the electronic device 2200.

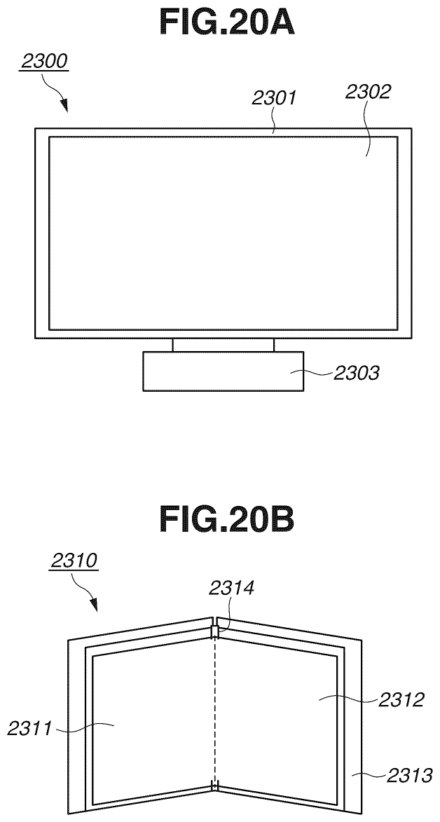

FIGS. 20A and 20B are schematic diagrams illustrating examples of the display apparatus according to the present exemplary embodiment. FIG. 20A illustrates a display apparatus 2300 such as a TV monitor or a PC monitor. The display apparatus 2300 includes a frame 2301 and a display unit 2302. The light emitting apparatus according to the present exemplary embodiment may be used for the display unit 2302.

The display apparatus 2300 includes the frame 2301 and a base 2303 for supporting the display unit 2302. A type of the base 2303 is not limited to the type illustrated in FIG. 20A. A lower side of the frame 2301 may serve as a base.

Further, each of the frame 2301 and the display unit 2302 may have a curved shape. A curvature radius of the curved shape may be 5000 mm or more and 6000 mm or less.

FIG. 20B is a schematic diagram illustrating another example of the display apparatus according to the present exemplary embodiment. A display apparatus 2310 in FIG. 20B is a so-called foldable display apparatus capable of being folded. The display apparatus 2310 includes a first display portion 2311, a second display portion 2312, a housing 2313, and a folding point 2314. Each of the first display portion 2311 and the second display portion 2312 may include the light emitting apparatus according to the present exemplary embodiment. The first display portion 2311 and the second display portion 2312 may constitute a single seamless display apparatus. The first display portion 2311 and the second display portion 2312 can be divided at the folding point 2314. The first display portion 2311 and the second display portion 2312 may respectively display different images, or may display one image cooperatively.

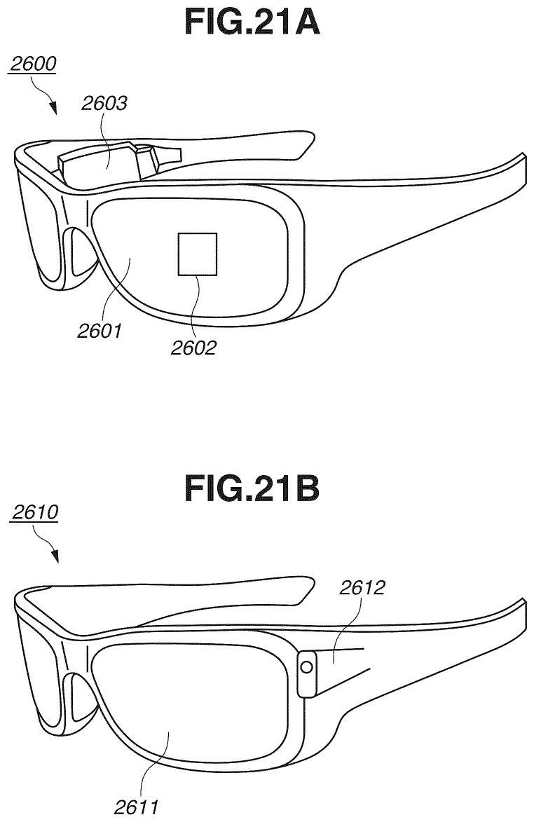

FIGS. 21A and 21B are schematic diagrams illustrating examples of a wearable device according to the present exemplary embodiment. The wearable device can be applied to a system which is wearable as a wearable device, e.g., smart glasses, a head-mounted display (HMD), or smart contact lenses. The image capturing display apparatus used for the above described application examples includes an image capturing apparatus capable of photoelectrically converting visible light into electric signals and a display apparatus capable of emitting visible light.

FIG. 21A is a diagram illustrating glasses (smart glasses) 2600 according to one application example. An image capturing apparatus 2602 such as a complementary metal-oxide semiconductor (CMOS) sensor or a single-photon avalanche diode (SAPD) is arranged on each of the front faces of lenses 2601 included in the glasses 2600. Further, the display apparatus according to the above-described exemplary embodiment is arranged on each of the back faces of the lenses 2601.

The glasses 2600 further include a control apparatus 2603. The control apparatus 2603 functions as a power source for supplying power to the image capturing apparatus 2602 and the display apparatus according to the above-described exemplary embodiment. Further, the control apparatus 2603 controls operations of the image capturing apparatus 2602 and the display apparatus. An optical system for condensing light to the image capturing apparatus 2602 is formed on each of the lenses 2601.

FIG. 21B is a diagram illustrating glasses (smart glasses) 2610 according to one application example. The glasses 2610 include a control apparatus 2612. An image capturing apparatus corresponding to the image capturing apparatus 2602 and a display apparatus are mounted on the control apparatus 2612. An optical system for projecting light emitted from the display apparatus mounted on the control apparatus 2612 is formed on each of lenses 2611, so that an image is projected on each of the lenses 2611. The control apparatus 2612 functions as a power source for supplying power to the image capturing apparatus and the display apparatus, and also controls operations of the image capturing apparatus and the display apparatus. The control apparatus 2612 includes an image control unit, and the image control unit transmits an image control signal to a peripheral circuit of the light emitting apparatus. The control apparatus 2612 may also include a line-of-sight detection unit for detecting a line-of-sight of the user wearing the glasses 2610. Infrared light may be used to detect the line-of-sight. An infrared light emitting unit emits infrared light to the eyeballs of the user who is gazing at a displayed image. An image capturing unit which includes a light receiving element detects the emitted infrared light reflected on the eyeball, so that a captured image of the eyeball can be acquired. By arranging a reduction unit for reducing light emitted to a display portion from the infrared light emitting unit in a planar view, degradation of image quality can be reduced.

The line-of-sight of the user gazing at the display image is detected from the captured image of the eyeball acquired through the infrared light image capturing. An optional known method can be used for the line-of-sight detection using the captured image of the eyeball. For example, it is possible to employ a method of detecting a line-of-sight based on a Purkinje image acquired from irradiation light reflected on the cornea.

More specifically, line-of-sight detection processing based on a pupil-corneal reflection method is executed. In the pupil-corneal reflection method, a line-of-sight vector which expresses the orientation (rotation angle) of the eyeball is calculated based on a pupil image and a Purkinje image included in the captured image of the eyeball, and a user's line-of-sight is detected from the calculated line-of-sight vector.

The display apparatus according to an exemplary embodiment of the present disclosure includes an image capturing apparatus including a light emitting element, and controls a display image displayed on the display apparatus based on the user's line-of-sight information received from the image capturing apparatus.

Specifically, based on the line-of-sight information, the display apparatus determines a first display region where the user is gazing at, and a second display region different from the first display region. The first display region and the second display region may be determined by a control apparatus included in the display apparatus, or the display apparatus may receive the information about the first display region and the second display region determined by an external control apparatus. In the display region of the display apparatus, the display resolution may be controlled so that the display resolution in the first display region becomes higher than the display resolution in the second display region. In other words, the resolution of the second display region may be lower than the resolution of the first display region.

Further, the first display region and the second display region in the display region may be determined based on the line-of-sight information. In addition, an artificial intelligence (AI) program may be used to determine the first display region or a high-priority region. The AI program may be a model which estimates a line-of-sight angle and a distance to the object, to which the line-of-sight is directed, from the image of the eyeball, based on teaching data which describes the image of the eyeball and the actual gazing direction of the eyeball captured in the image. The AI program may be included in the display apparatus or the image capturing apparatus, or may be included in an external apparatus. In a case where the AI program is included in the external apparatus, a result of the estimation is transmitted to the display apparatus through communication.

The present exemplary embodiment can preferably be applied to smart glasses further including an image capturing apparatus for capturing an image of the outside, in a case where display control is executed based on visual recognition detection. The smart glasses can display information about the captured outside image in real time.

As described above, according to the present disclosure, it is possible to provide a light emitting apparatus including a light emitting element whose leak currents are reduced.

According to the present disclosure, it is possible to provide a light emitting apparatus including a pixel whose leak currents are reduced.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-014806, filed Feb. 2, 2024, which is hereby incorporated by reference herein in its entirety.

What is claimed is:

1. A light emitting apparatus comprising:
a light emitting element;
a silicon substrate;
a first transistor and a second transistor arranged on a first face of the silicon substrate;
a peripheral circuit for supplying an image signal to the first transistor; and
a third transistor arranged on the peripheral circuit,
wherein each of the first transistor, the second transistor, and third transition includes a source and a drain,
wherein the second transistor includes a gate electrode,
wherein any one of the source and the drain of the first transistor is connected to the gate electrode of the second transistor,
wherein any one of the source and the drain of the second transistor is connected to the light emitting element,
wherein an impurity concentration in a diffusion region of each of the source and the drain of the second transistor has a concentration distribution having a concentration peak in a first direction heading toward the drain from the source,
wherein an impurity concentration in a diffusion region of each of the source and the drain of the third transistor has a concentration distribution having a concentration peak in a second direction heading toward the drain from the source, and
wherein a peak concentration of impurities in the diffusion region of the source or the drain of the second transistor is smaller than a peak concentration of impurities in the diffusion region of the source or the drain of the third transistor.

2. The light emitting apparatus according to claim 1,
wherein an impurity concentration in a diffusion region of each of the source and the drain of the first transistor has a concentration distribution having a concentration peak in a third direction heading toward the drain from the source,
wherein the impurity concentration in the diffusion region of each of the source and the drain of the third transistor has a concentration distribution having a concentration peak in the second direction heading toward the drain from the source, and
wherein a peak concentration of impurities in the diffusion region of the source or the drain of the first transistor is smaller than the peak concentration of impurities in the diffusion region of the source or the drain of the third transistor.

3. The light emitting apparatus according to claim 1, further comprising a fourth transistor arranged between a power source for supplying electric currents to the light emitting element and the second transistor,
wherein the fourth transistor includes a source, a drain, and a gate electrode,
wherein an impurity concentration in a diffusion region of each of the source and the drain of the fourth transistor has a concentration distribution having a concentration peak in a fourth direction heading toward the drain from the source, and
wherein a peak concentration of impurities in the diffusion region of the source or the drain of the fourth transistor is smaller than the peak concentration of impurities in the diffusion region of the source or the drain of the third transistor.

4. The light emitting apparatus according to claim 1, further comprising a fifth transistor arranged between a terminal of the drain or the source of the second transistor connected to the light emitting element and a terminal having a potential lower than a potential of the power source for supplying electric currents to the light emitting element,
wherein an impurity concentration in a diffusion region of each of the source and the drain of the fifth transistor has a concentration distribution having a concentration peak in a fifth direction heading toward the drain from the source, and
wherein a peak concentration of impurities in the diffusion region of the source or the drain of the fifth transistor is smaller than the peak concentration of impurities in the diffusion region of the source or the drain of the third transistor.

5. The light emitting apparatus according to claim 1, wherein the first transistor includes a Halo injection layer in the diffusion region of each of the source and the drain, the Halo injection layer having a polarity opposite to a polarity of the diffusion region.

6. The light emitting apparatus according to claim 5, wherein the third transistor includes a Halo injection layer in the diffusion region of each of the source and the drain, the Halo injection layer having a polarity opposite to a polarity of the diffusion region, and
wherein a peak concentration of an impurity concentration in the Halo injection layer included in the first transistor is different from a peak concentration of an impurity concentration in the Halo injection layer included in the third transistor.

7. The light emitting apparatus according to claim 1, further comprising a fourth transistor arranged between a power source for supplying electric currents to the light emitting element and the second transistor,
wherein the fourth transistor includes a Halo injection layer in a diffusion region of each of a source and a drain,
wherein the Halo injection layer has a polarity opposite to a polarity of the diffusion region, and
wherein a peak concentration of an impurity concentration in a Halo injection layer included in the third transistor is different from a peak concentration of an impurity concentration in the Halo injection layer included in the fourth transistor.

8. The light emitting apparatus according to claim 1, further comprising a fifth transistor arranged between a terminal of the drain or the source of the second transistor connected to the light emitting element and a terminal having a potential lower than a potential of a power source for supplying electric currents to the light emitting element,
wherein the fifth transistor includes a Halo injection layer in a diffusion region of each of a source and a drain, the Halo injection layer having a polarity opposite to a polarity of the diffusion region, and
wherein a peak concentration of an impurity concentration in a Halo injection layer included in the third transistor is different from a peak concentration of an impurity concentration in the Halo injection layer included in the fifth transistor.

9. The light emitting apparatus according to claim 1, wherein the peripheral circuit is arranged on the first face of the silicon substrate.

10. The light emitting apparatus according to claim 1, wherein the peripheral circuit is arranged on a second silicon substrate different from the silicon substrate.

11. A light emitting apparatus comprising:
a light emitting element;
a silicon substrate;
a first transistor and a second transistor arranged on a first face of the silicon substrate;
a peripheral circuit for supplying an image signal to the first transistor; and
a third transistor arranged on the peripheral circuit,
wherein each of the first transistor, the second transistor, and third transition includes a source and a drain,
wherein the second transistor includes a gate electrode,
wherein any one of the source and the drain of the first transistor is connected to the gate electrode of the second transistor,
wherein any one of the source and the drain of the second transistor is connected to the light emitting element,
wherein an impurity concentration in a diffusion region of each of the source and the drain of the first transistor has a concentration distribution having a concentration peak in a third direction heading toward the drain from the source,
wherein an impurity concentration in a diffusion region of each of the source and the drain of the third transistor has a concentration distribution having a concentration peak in a second direction heading toward the drain from the source, and
wherein a peak concentration of impurities in the diffusion region of the source or the drain of the first transistor is smaller than a peak concentration of impurities in the diffusion region of the source or the drain of the third transistor.

12. The light emitting apparatus according to claim 11, further comprising:
a power source for supplying electric currents to the light emitting element; and
a fourth transistor arranged between the power source and the second transistor,
wherein the fourth transistor includes a source, a drain, and a gate electrode,
wherein an impurity concentration in a diffusion region of each of the source and the drain of the fourth transistor has a concentration distribution having a concentration peak in a fourth direction heading toward the drain from the source, and
wherein a peak concentration of impurities in the diffusion region of the source or the drain of the fourth transistor is smaller than the peak concentration of impurities in the diffusion region of the source or the drain of the third transistor.

13. The light emitting apparatus according to claim 11, further comprising a fifth transistor arranged between a terminal of the drain or the source of the second transistor connected to the light emitting element and a terminal having a potential lower than a potential of the power source for supplying electric currents to the light emitting element,
wherein an impurity concentration in a diffusion region of each of the source and the drain of the fifth transistor has a concentration distribution having a concentration peak in a fifth direction heading toward the drain from the source, and
wherein a peak concentration of impurities in the diffusion region of the source or the drain of the fifth transistor is smaller than the peak concentration of impurities in the diffusion region of the source or the drain of the third transistor.

14. The light emitting apparatus according to claim 11, wherein the peripheral circuit is arranged on the first face of the silicon substrate.

15. The light emitting apparatus according to claim 11, further comprising:
a second silicon substrate different from the silicon substrate,
wherein the peripheral circuit is arranged on the second silicon substrate.

16. A display apparatus according to claim 1, further comprising:
an image control unit configured to transmit an image control signal to the peripheral circuit,
wherein the light emitting element emits light according to the image control signal.

17. A photoelectric conversion apparatus comprising:
an optical unit including a plurality of lenses;
an image sensor configured to receive light passing through the optical unit; and
a display unit configured to display an image captured by the image sensor,
wherein the display unit is the display apparatus according to claim 16.

18. An electronic device comprising:
the display apparatus according to claim 16;
a housing on which the display apparatus is arranged; and
a communication unit arranged on the housing, configured to communicate with a remote external apparatus.
